(19) United States
(12) Patent Application Publication
(10) Pub. No.: US 2020/0098547 A1
(43) Pub. Date: Mar. 26, 2020

(54) GAS DISTRIBUTION ASSEMBLIES AND OPERATION THEREOF

(71) Applicant: Applied Materials, Inc., Santa Clara, CA (US)

(72) Inventors: Priyanka DASH, Menlo Park, CA (US); Zhijun JIANG, Sunnyvale, CA (US); Ganesh BALASUBRAMANIAN, Fremont, CA (US); Qiang MA, Cupertino, CA (US); Kalyanjit GHOSH, Pleasanton, CA (US); Kaushik ALAYAVALLI, Sunnyvale, CA (US); Yuxing ZHANG, Santa Clara, CA (US); Daniel HWUNG, Los Gatos, CA (US); Shawyon JAFARI, Sunnyvale, CA (US)

(21) Appl. No.: 16/583,003

(22) Filed: Sep. 25, 2019

Related U.S. Application Data
(60) Provisional application No. 62/736,882, filed on Sep. 26, 2018.

(51) Int. Cl. H01J 37/32; H01L 21/67; C23C 16/44

(52) U.S. Cl. CPC H01J 37/32449; H01L 21/67253; C23C 16/4401; H01L 21/67288; H01J 37/32642

(57) ABSTRACT

Systems and methods for a process chamber that decreases the severity and occurrence of substrate defects due to loosened scale is discussed herein. A gas distribution assembly is disposed in a process chamber and includes a faceplate with a plurality of apertures formed therethrough and a second member. The faceplate is coupled to the second member which is configured to couple to the faceplate to reduce an exposed area of the faceplate and minimize an available area for material buildup during the release of gas into the process chamber. The second member is further configured to improve the glow of precursors into the process chamber. The gas distribution assembly can be heated before and during process chamber operations, and can remain heated between process chamber operations.

### CROSS-REFERENCE TO RELATED APPLICATIONS

This application claims benefit of U.S. provisional patent application Ser. No. 62/736,882, filed Sep. 26, 2018, which is herein incorporated by reference.

### BACKGROUND

### Field

Embodiments of the present disclosure generally relate to semiconductor device fabrication.

### Description of the Related Art

Semiconductor fabrication includes numerous operations such as the formation and/or patterning of films of varying compositions and thicknesses. Film formation can each be performed by delivering one or more gases to a process chamber. When gases are introduced to the process chamber, a gas flow path is created from the entry point of the gases into the process chamber. The gases can be trapped in dead zones, and thus build up a scale on chamber surfaces in the dead zone areas. The scale can loosen, flake, and peel from the chamber surfaces in the dead zone areas, landing on substrates and process chamber components. The substrates can have defects resulting from the loosened scale, which can affect downstream operations. As films of increasing thickness are formed on a substrate during semiconductor device fabrication, the film formation time increases. The increased formation time results in increased buildup of scale on the chamber surfaces in the dead zones, and increased frequency and severity of defects on substrates.

Thus, there remains a need for an improved system for and method of providing gases to process chambers.

### SUMMARY

In an embodiment, a process chamber, including: a gas distribution assembly disposed in the process chamber, the gas distribution assembly including a faceplate comprising a first portion including a plurality of apertures formed therethrough and a second portion disposed radially outward of the first portion, the second portion including a planar surface, wherein at least one heating element is embedded in the faceplate, and a member coupled to the second portion of the faceplate, the member located on a process-region side of the faceplate and surrounding the plurality of apertures.

In an embodiment, a method of using a process chamber, including: heating a faceplate of a gas distribution assembly disposed in a process chamber opposite a substrate support to a first temperature, the faceplate including a plurality of apertures formed therethrough and a member coupled to the faceplate, the member being located on a process-region side of the faceplate and surrounding the plurality of apertures; and heating a substrate support disposed in the process chamber to a second temperature. Further in the embodiment, the method includes providing, via the plurality of apertures of the faceplate, while a substrate is disposed on the substrate support, a first gas of a first composition to the process chamber while the gas distribution assembly is at or above the second temperature. Furthermore in the embodiment, the method includes, in response to providing the first gas to the process chamber, at least one of: forming a first film on the substrate; or removing at least a portion of a previously-formed film on the substrate.

In an embodiment, a process chamber comprises: a liner disposed along a wall of the process chamber; and a gas distribution assembly. The gas distribution assembly comprising: a faceplate comprising a first portion including a plurality of apertures formed therethrough and a second portion disposed radially outward of the first portion, the second portion including a planar surface; at least one heating element embedded in the faceplate; and a member coupled to the second portion of the faceplate, the member located on a process-region side of the faceplate, wherein a first outer surface of the member is in contact with the liner, a second outer surface of the member is in contact with the second portion of the faceplate, and an inner surface of the member connects the first outer surface to the second outer surface. The process chamber further comprises a substrate support disposed opposite the gas distribution assembly; and a power supply coupled to the at least one heating element in the gas distribution assembly and to the substrate support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic illustration of a substrate processing system including a system according to embodiments of the present disclosure.

FIG. 2A is a schematic illustration of a bottom view of a faceplate of a gas distribution assembly according to embodiments of the present disclosure.

FIG. 2B is a schematic illustration of a bottom view of a second member of a gas distribution assembly according to embodiments of the present disclosure.

FIG. 3 is a schematic illustration of a bottom view of a gas distribution assembly according to embodiments of the present disclosure.

FIGS. 4A-4E are partial schematic section views of inner surfaces of gas distribution assemblies according to various embodiments of the present disclosure.

FIG. 5 is a method of using a process chamber according to embodiments of the present disclosure.

### DETAILED DESCRIPTION

Semiconductor device fabrication includes the formation of one or more films or film stacks on a substrate. The films, which can include oxides, nitrides, oxy-nitrides, metallic materials, and combinations thereof, can be formed, patterned, capped, annealed, or undergo other operations to form various semiconductor devices. Some semiconductor device fabrication operations include introducing one or more gases to a process chamber. The gases can build up on surfaces of the process chamber, including surfaces of a gas distribution assembly with apertures formed therethrough and configured to distribute the gas(es) within the process chamber. In some embodiments, the areas of the gas distribution assembly or other parts of a process chamber where buildup occurs can be referred to as dead zones. A “dead zone” as discussed herein refers to an area in the process chamber, including on the gas distribution assembly, where gases including gaseous precursors are outside of a gas flow path. The gases outside of the gas flow path can thus cause undesired material buildup on chamber surfaces since this portion of the gas(es) are not directed towards the substrate.

For example, when one or more precursor gases are introduced into the process chamber to form a film on a substrate, there can be buildup of material in a dead zone. The dead zone can be located towards the periphery of the gas distribution assembly on one or more surfaces where apertures are not present. The material formed in the dead zone, referred to herein as scale and/or buildup, can loosen, e.g., flake, peel, or otherwise disassociate from the chamber surfaces and can become suspended in a plasma in the chamber. During a subsequent plasma purge operation in the process chamber, the material is no longer suspended in the plasma and thus falls on to the substrate, causing substrate defects that can negatively impact device fabrication. The buildup in the dead zone can also negatively impact the ability to process multiple substrates sequentially or to perform multiple film depositions in the process chamber without cleaning some or all of the process chamber surfaces.

Using the systems and methods discussed herein, the substrate defects caused by dead zone build up in process chambers are reduced or eliminated. The process chambers discussed herein can include a chemical vapor deposition (CVD) process chamber or other chambers configured to introduce one or more gases to a process volume via one or more gas distribution assemblies. The gas distribution assembly is configured to reduce the likelihood and/or severity of buildup in dead zones by minimizing an area of the gas exposed to the gas and by heating the gas distribution assembly to a temperature of up to about 350° C.

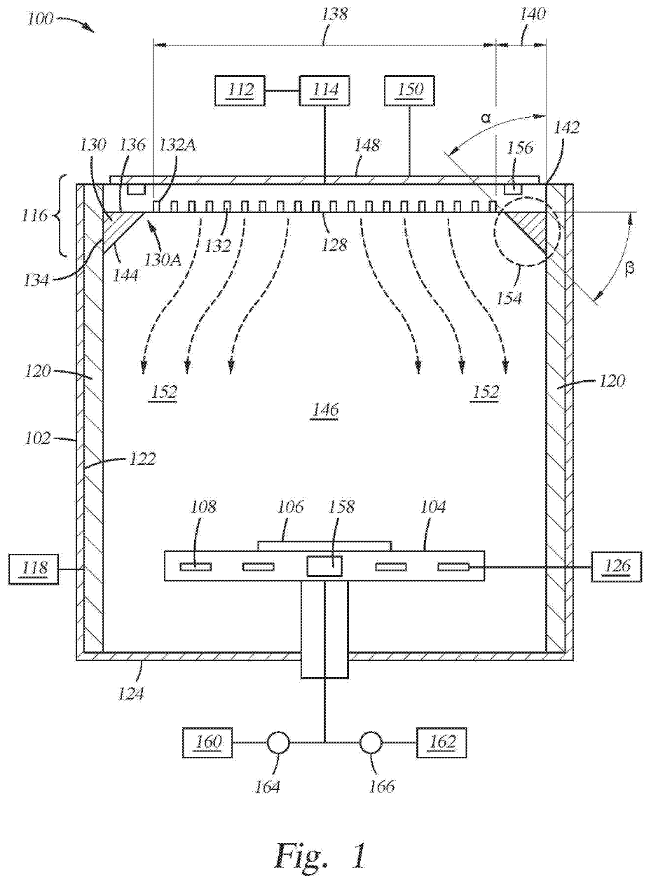

FIG. 1 is a schematic illustration of a substrate processing system that includes a system 100, according to embodiments of the present disclosure. The system 100 includes a process chamber 102 having a substrate support 104 disposed within a process volume 146 of the process chamber 102. In some example, the substrate support 104 can be configured as a substrate support pedestal. A process volume 146 can be defined, for example, between the substrate support 104 and the gas distribution assembly 116. In some embodiments, the substrate support 104 may include a mechanism that retains or supports a substrate 106 on top surface of the substrate support 104. Exemplary retention mechanisms may include an electrostatic chuck, a vacuum chuck, a substrate retaining clamp, or the like. The substrate support 104 may include mechanisms for controlling the substrate temperature (such as heating and/or cooling devices) and/or for controlling the species flux and/or ion energy proximate the substrate surface. In one example, the substrate support 104 can have one or more substrate support heating elements 108 disposed therein or otherwise thermally coupled to the substrate support 104. In alternate examples, the process chamber 102 can have one or more radiant heat lamps positioned to illuminate the substrate 106 and/or the substrate support 104. One or more power source 126 can be configured to heat the substrate support 104 to a predetermined temperature, for example, from about 250° C. to about 350° C. In an embodiment, the power source 126 is configured to provide at least 5 kW of energy.

In some examples, the substrate support 104 may include an electrode 158 and one or more power sources such as a first bias power source 160 and a second bias power source 162. Each bias power source 160, 162 is coupled to the electrode 158 via a first matching network 164 and a second matching network 166, respectively. For example, the substrate support 104 may be configured as a cathode coupled to a first bias power source 160 via a first matching network 164. The above described bias power sources 160, 162 may be capable of producing up to 12,000 W of energy at a frequency of about 2 MHz, or about 13.56 MHz, or about 60 Mhz. The at least one bias power source 160, 162 may provide either continuous or pulsed power. In some embodiments, the bias power source 160, 162 may alternatively be a DC or pulsed DC source.

A gas distribution assembly 116 is disposed in the process chamber 102 opposite the substrate support 104. The gas distribution assembly 116 includes a faceplate 128 or a first member coupled to a second member 130 on a process-side region of the faceplate 128. The faceplate 128 can be formed from a metal such as aluminum or stainless steel and includes a plurality of heating elements 156 that are coupled to the one or more power sources 126. The faceplate 128 can be heated from about 270° C. to about 350° C. before and/or during one or more operations in the process chamber 102, such as a film deposition operation. In some examples, the faceplate 128 is held at the temperature from about 270° C. to about 350° C. during a first operation in the process chamber 102, and maintained at or above the deposition temperature of the first operation during a second, subsequent operation in the process chamber. In one example, the second operation can be executed on the same substrate as the first operation. In another example, the second operation can be executed on a second, different substrate, as discussed in detail below. In some examples, the gas distribution assembly 116 is coupled to an RF source (not shown) configured to provide power to the gas distribution assembly before, during, and/or after operations within the process chamber 102.

In an embodiment, the faceplate 128 can be fabricated from aluminum, and can be coated by an oxide such as aluminum oxide (Al₂O₃). The second member 130 can be fabricated Al₂O₃. The faceplate 128 further includes a plurality of apertures 132 formed therethrough, such that the gas introduced from the gas manifold 114 into the process chamber 102 is introduced to the process volume 146 via the plurality of apertures 132. The plurality of apertures 132 are formed in a first portion 138 of the faceplate 128. A second portion 140 of the faceplate 128, disposed radially outward of the first portion, does not include apertures. The second portion 140 of the faceplate 128 can be referred to as a peripheral portion of the faceplate 128. The second portion 140 extends from an outer edge 142 of the faceplate 128 to the plurality of apertures 132. In such an example, the second portion 140 is disposed concentrically about the first portion 138. The plurality of apertures 132 can be arranged in various configurations across the surface of the faceplate 128, including as concentric rings, ring clusters, randomly positioned clusters, or other geometric shapes depending upon the embodiment. In some examples, the faceplate 128 includes zone heating such that the one or more heating elements 156 can be controlled individually or in groups to create a zones of varying temperatures across the faceplate 128.

The second member 130 is a circular member positioned adjacent and/or in intact with the faceplate 128 and the liner 120 of the process chamber 102. The second member 130 is defined in part by a first outer surface 134, a second outer surface 136, and an inner surface 144 that is a transitional surface, extending between the first outer surface 134 and the second outer surface 136. The first outer surface 134 of the second member 130 is thus positioned in proximity to the liner 120 such that the liner 120 is flush with (in direct contact or with an adhesive disposed in therebetween) the first outer surface 134. The second outer surface 136 is coupled to a lower surface of the faceplate 128. In one example, the second outer surface 136 has a length equal to or less than the adjacent second portion 140 of the faceplate 128. The inner surface 144 can be at an angle α from 1-89 degrees, such as from 10 to 70 degrees, or from 20 to 60 degrees, or from 30 to 60 degrees, such as 40 to 50 degrees, for example, about 45 degrees. The angle β is equal to 90 degrees minus α. In such an example, the second member 130 has a cross-section that forms a right triangle. However it is contemplated that, in some examples, the cross-section of the second member 130 may not be a right triangle, and the angle β may not equal 90 degrees minus the angle α.

The temperature of the gas distribution assembly 116 can be established prior to positioning the substrate 106 in the process chamber 102. The temperature of the gas distribution assembly 116 can be held or modified within a predetermined temperature range during the formation of one or more films in the process chamber 102. The elevated temperature of the gas distribution assembly 116 promotes gas flow into the process chamber 102 in part by reducing the temperature differential between the gas distribution assembly 116 and the substrate support 104 upon which the substrate 106 is positioned. The reduced temperature differential causes less diffusion of species from hot areas to cold areas, and/or less mass diffusion. The improved gas flow can lessen the occurrence and severity of buildup since flowing (moving) gas is less likely to cause build up, in contrast to gas trapped outside of a gas flow. The elevated temperature of the gas distribution assembly 116 also reduces the occurrence and/or the severity of buildup on the gas distribution assembly 116.

Additionally or alternatively, the elevated temperature of the gas distribution assembly 116 causes buildup that does occur to be less brittle and therefore less likely to loosen and cause defects. In one example, the temperature of the gas distribution assembly 116 can be controlled by applying power to one or more heating elements 156. In one example, the gas distribution assembly 116 can have the plurality of heating elements 156 disposed therein configured to create a temperature gradient and/or temperature zones across the faceplate. The plurality of heating elements 156 can be used to raise, lower, or maintain the temperature of the faceplate 128, which is part of the gas distribution assembly 116. Thus, the temperature of the gas distribution assembly 116 discussed herein can be measured as the temperature of the faceplate 128.

In one example, the gas distribution assembly 116 can be further coupled to a chiller plate 148. In one example, when the chiller plate 148 is coupled to the gas distribution assembly 116, the chiller plate 148 facilitates control over a temperature or a temperature gradient across the faceplate 128 during, for example, the deposition of one or more films on the substrate 106. In some embodiments, the chiller plate 148 includes a plurality of channels (not shown) formed in the chiller plate 148. The plurality of channels allow a temperature control fluid provided by a temperature control fluid supply (chiller) 150 to flow through the chiller plate 148 to facilitate the control over the temperature of the faceplate 128.

In some examples, not pictured here, a remote plasma source can be used to deliver plasma to the process chamber 102 and can be coupled to the gas distribution assembly 116. One or more gas sources 112 are coupled to the process chamber 102 via a gas manifold 114. The gas manifold 114 is coupled to the gas distribution assembly 116 configured to deliver the one or more gases from the one or more gas sources 112 to the process volume 146. Each of the one or more gas sources 112 can contain a carrier gas, a precursor to film formation. In an embodiment, a liner 120 is disposed along the sidewall 122 of the process volume 146. In alternate embodiments, not shown here, the liner 120 can be further disposed along a bottom surface 124 of the process chamber 102.

When one or more gases are introduced via the plurality of apertures 132, the gases are introduced into the process volume 146 via a plurality of gas flow paths 152. The gas flow paths 152 extend from the plurality of apertures 132. The second member 130, and particularly a shape of the inner surface 144 thereof, influences the flow paths 152 within the process volume 146. While the inner surface 144 is shown in FIG. 1 as a flat surface, in alternate embodiments, the inner surface 144 can be a concave surface configured to promote formation of the gas flow path towards the liner 120 and/or the substrate 106 as to inhibit formation of a dead zone. In alternate embodiments, the inner surface 144 is otherwise angled outward from the faceplate 128 towards the liner 120 to reduce or eliminate dead zones, thus reducing substrate defects caused by material buildup in the dead zones. In some examples, there is a dead zone 154 where gas does not flow and where scale can accumulate during the introduction of one or more gases via the gas manifold 114. In one example, the dead zone 154 is positioned radially outward of the substrate support 104.

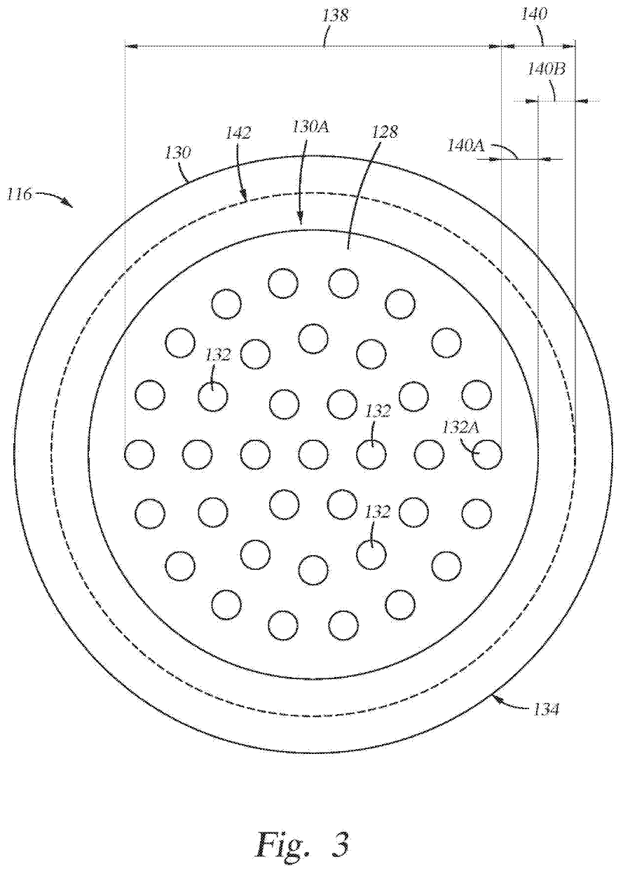

In an embodiment, a distance 140A (shown below in FIG. 3) from an outer aperture 132A and the second portion 140 can be as few as 0 nm, such that the first portion 138 ends and the second portion 140 begins at the outer aperture 132A. In one example, the second portion 140 does not include any of the plurality of apertures 132. In some examples, the plurality of apertures 132 increases in density towards the outer edge 142 of the faceplate 128 such that the outer aperture 132A is associated with a subset of the plurality of apertures 132 that have a higher density as compared to the position of the apertures outside of the subset. In one example, the plurality of apertures 132 has a density gradient, where the density of the plurality of apertures 132 increases towards the outer edge 142. In another example, the subset of apertures closest to the outer edge 142 of the faceplate 128 is associated with a higher density than the remainder of the plurality of apertures 132. The outer aperture 132A is shown in FIG. 1 as a single aperture, but can be one or more aperture of the plurality of apertures 132 that has an outside edge closest to the outer edge 142 of the faceplate 128.

By minimizing the distance from the outer aperture 132A to the innermost edge 130A of the second portion 140, there is a reduced surface area available for precursor buildup as compared to conventional gas distribution assemblies. The reduced surface area on the faceplate 128 that is available for buildup decreases the occurrence and/or severity of substrate defects that can result from particulates flaking from the buildup area. One or more exhaust systems 118 can be coupled to the process chamber 102 and used to remove excess process gases or by-products from the process volume 146 during processing, or in between subsequent film depositions on one or more substrates.

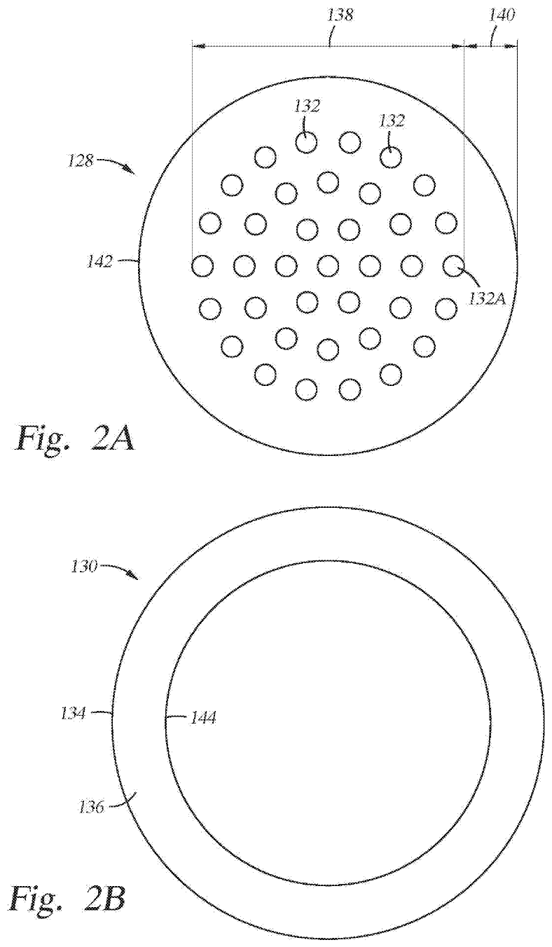

FIG. 2A is a schematic illustration of a bottom view of a faceplate 128 of a gas distribution assembly according to embodiments of the present disclosure. FIG. 2A shows the faceplate 128, including the plurality of apertures 132 formed in the first portion 138. FIG. 2A also shows the second portion 140 of the faceplate 128 that extends from the outer edge 142 to an outer aperture 132A. The outer edge 142 of the faceplate 128 is circular in shape and has a smooth, curved surface. In alternate embodiments, the outer edge 142 or other surfaces or edges of the faceplate 128 can further include bevels, cooling channels, mating features, or other features to facilitate coupling to the second member 130 or to otherwise cause the gas distribution assembly 116 in FIG. 1 to perform gas delivery functions during operation of the process chamber 102. While the faceplate is shown as circular, other shapes and configurations are contemplated, include oval, square, or rectangular.

FIG. 2B is a schematic illustration of a bottom view of a second member 130 of a gas distribution assembly according to embodiments of the present disclosure. The second member 130 is a ring-shaped member having a central opening. FIG. 2B shows the first outer surface 134, the second outer surface 136, and the inner surface 144 that is a transitional surface between the first outer surface 134 and the second outer surface 136. In FIG. 2B, the first outer surface 134, the second outer surface 136, and the inner surface 144 are illustrated as either flat and/or smooth surfaces. In alternate embodiments, there can be bevels, cooling channels, mating features, or other features included in the second member 130. While the second member 130 is shown as a ring-shaped member having a central opening, it is contemplated that the second member 130 may take the form of other shapes having a central opening, including oval, square, or rectangle.

FIG. 3 is a schematic illustration of a bottom view of a gas distribution assembly 116 such as the gas distribution assembly 116 in FIG. 1. To form the gas distribution assembly shown in FIG. 3, the faceplate 128 is coupled, in some cases permanently coupled, to the second member 130. During coupling, some of the second portion 140 or the entirety of the second portion 140 of the faceplate 128 is covered by the second member 130. The coupling reduces surface area (indicated by the distance 140A) of the second portion 140 exposed to the process volume 146 (shown in FIG. 1). The reduced surface area minimizes the surface area on which scale can form.

As shown in FIG. 3, the distance 140A extends from the outer aperture 132A to the innermost edge 130A of the second portion 140, and is shown as being greater than 0 mm in FIG. 3. In an example in FIG. 3, a region 140B is formed where the faceplate 128 and the second member 130 overlap, and the outside edge 142 of the faceplate 128 is shown by the dashed line. In another example, shown in FIG. 1 but not in FIG. 3, the outer edge 142 of the faceplate 128 is flush with the outer edge 134 of the second member so the region 140B would extend to the outer edge 134 of the second member. In some examples, the distance 140A can be 0 mm, such that the innermost edge 130A is flush with an outermost edge of the outer aperture 132A. The coupling of the faceplate 128 and the second member 130 reduces the area of the faceplate 128 that is exposed to the precursor gas, thus reducing the size of dead zone where scale can form during process chamber operations as compared to conventional chamber configurations.

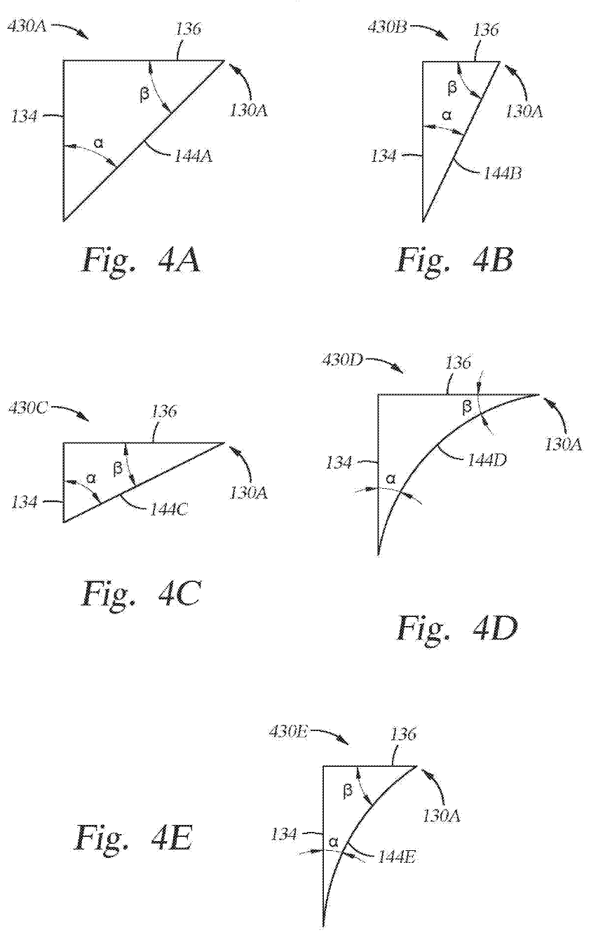

FIGS. 4A-4E are partial schematic section views of second members according to various embodiments of the present disclosure. Each of the second members 430A-430E may individually be used in place of the second member 130 in FIG. 1. As discussed above, the gas distribution assemblies are configured to promote gas flow from the plurality of apertures as to reduce or eliminate the formation of dead zones on or near the gas distribution assembly where precursor material can build up and flake off on to substrates.

FIG. 4A illustrates a partial cross section view of a second member 430A, according to one embodiment. The second member 430A is substantially similar to the second member 130 in FIG. 1. The inner surface 144A of the second member 430A can be at an angle α from 1 to 89 degrees, such as from 10 to 70 degrees, or from 20 to 60 degrees, or from 30 to 60 degrees, such as 40 to 50 degrees, for example, about 45 degrees. In one embodiment, the angle α may be substantially equal to the angle β.

FIG. 4B illustrates a partial cross section view of a second member 430B, according to another embodiment. The second member 430B is substantially similar to the second member 130 in FIG. 1. The inner surface 144B of the second member 430B can be at an angle α from 1 to 89 degrees, such as from 10 to 70 degrees, or from 20 to 60 degrees, or from 30 to 60 degrees, such as 40 to 50 degrees, for example, about 45 degrees, and at an angle β of 1 to 89 degrees, such as from 10 to 70 degrees, or from 20 to 60 degrees, or from 30 to60 degrees, such as 40 to 50 degrees, for example, about 45 degrees. In one example, the angle α in FIG. 4A can be less than the angle α in FIG. 4B, and the angle β in FIG. 4A can be substantially the same as the angle β in FIG. 4B. In another example, the angle α may be less than the angle β in FIG. 4B. In one example, angle α is equal to 90 degrees minus angle R.

FIG. 4C illustrates a partial cross section view of a second member 430C, according to yet another embodiment. The second member 430C is substantially similar to the second member 130 in FIG. 1. The inner surface 144C of the second member 430C can be at an angle α from 1-89 degrees relative to the first outer surface 134, such as about 1-60 degrees, such as about 1-45 degrees, such as about 1-30 degrees, such as about 45-89 degrees and at an angle β of 180 degrees minus angle α. In one example, the angle α in FIG. 4A can be substantially the same as the angle α in FIG. 4C, and the angle β in FIG. 4A can be greater than the angle β in FIG. 4C. In other words, the angle a may be greater than the angle β in FIG. 4C. While the inner surfaces 144A-144C are illustrated as being flat, in alternate embodiments, the surfaces can be concave as shown in FIGS. 4D and 4E, or otherwise configured to direct the gas flow outward from the apertures.

FIG. 4D illustrates a partial cross section view of a second member 430D, according to another embodiment. The second member 430D is substantially similar to the second member 130 in FIG. 1. The inner surface 144D of the second member 430D may be concave and can have an angle α from 1-89 degrees, such as about 1 to 60 degrees, such as about 1 to 45 degrees, such as about 1 to 30 degrees. An angle β may be about 1 to 60 degrees, such as about 1 to 45 degrees, such as about 1 to 30 degrees. In one embodiment, the angle α may be substantially equal to the angle β in FIG. 4D. In another embodiment, the angle α may be less than the angle β in FIG. 4D.

FIG. 4E illustrates a partial cross section view of a second member 430E, according to yet another embodiment. The second member 430E is substantially similar to the second member 130 in FIG. 1. The inner surface 144E of the second member 430E can be at an angle α of about 1 to 60 degrees, such as about 1 to 45 degrees, such as about 1 to 30 degrees. An angle β may be about 1 to 60 degrees, such as about 1 to 45 degrees, such as about 1 to 30 degrees. In one example, the angle α in FIG. 4D can be greater than the angle α in FIG. 4E, and the angle β in FIG. 4D can be substantially the same as the angle β in FIG. 4E. In other words, the angle α may be less than the angle β in FIG. 4E.

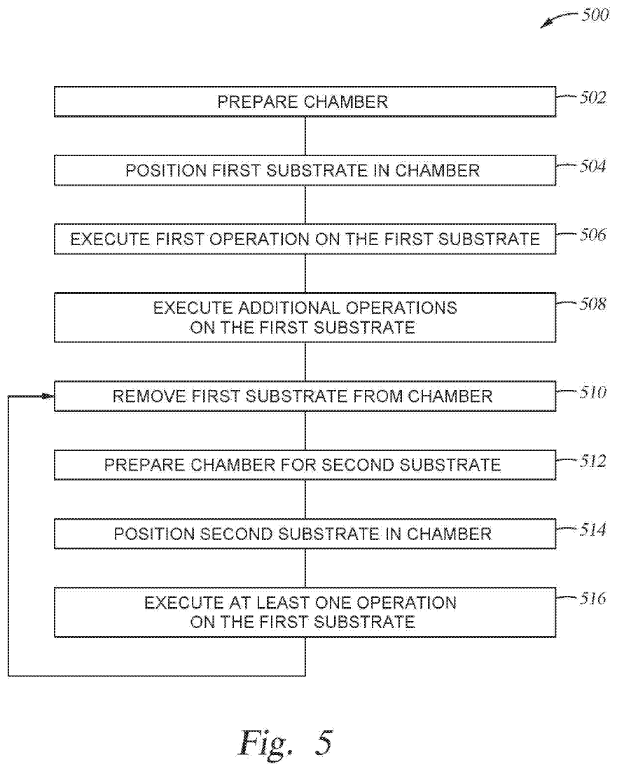

FIG. 5 is a method 500 of using a process chamber according to embodiments of the present disclosure. In the method 500, at operation 502, a process chamber is prepared to form one or more films on a substrate. Further during operation 502, a gas distribution assembly, such as the gas distribution assembly 116 in FIG. 1, can be heated via heating elements such as the plurality of heating elements 156 that are disposed in or otherwise coupled to the gas distribution assembly. The gas distribution assembly can be heated to a temperature from about 270° C. to about 350° C. at operation 502. The gas distribution assembly and the substrate support can be heated simultaneously, sequentially in any order, or in an overlapping fashion during operation 502.

At operation 504, a first substrate is positioned in the process chamber on the substrate support. The first substrate may include high aspect ratio features such as holes or vias where a depth of the feature is at least ten times (10×) a width of the feature. Operation 504 can further include heating a substrate support such as the substrate support 104 in FIG. 1. The heating of the substrate support at operation 504 can be performed via the one or more substrate support heating elements 108 (shown in FIG. 1) or via one or more radiant heat lamps. During operation 504 the substrate support can be heated from about 250° C. to about 350° C. In other examples, the substrate support can be heated prior to operation 504, for example, from previous chamber operations and/or to receive a substrate heated in a previous operation in a different chamber or system. In still other examples, the substrate support can be heated subsequent to operation 504. The first substrate is positioned in the process chamber at operation 504 while each of the gas distribution assembly and the substrate support are at or above the temperature established at operation 502. The first substrate can be a bare substrate with no layers formed thereon, or the first substrate can have one or more films formed thereon, such films or film stacks including one or more of a metal, an oxide, a nitride, or combinations thereof. Examples of substrates include silicon substrates, germanium substrates, or silicon-germanium substrates.

At operation 506, a first process is performed. In an embodiment, the first process at operation 506 includes introducing at least one gas to the process chamber via the gas distribution assembly. During operation 506, the temperature of the gas distribution assembly previously established at operation 502 is maintained between from about 270° C. to about 350° C. In one example, the first process at operation 506 includes introducing one or more precursor gases to form a film from about 2 microns to about 8 microns thick on the substrate, which may or may not already include previously-formed and/or previously-patterned films. In some examples, one or more carrier gases such as oxygen, hydrogen, or nitrogen can also be introduced during or before operation 506. In some examples, the temperature of the gas distribution assembly can be raised and/or lowered among and between at least operations 502-508 and 512-516 discussed herein within a range from about 270° C. to about 350° C.

In another example, when a plasma is generated during operation of the process chamber at operation 506, a plasma purge can occur as a part of operation 506. The use of a low pressure during the plasma purge at operation 506 can further include the use of low-frequency RF to facilitate plasma generation and/or control. The ion bombardment of the gas distribution assembly is controlled by controlling the gas flow which contributes towards the reduction in scale buildup and loosening in dead zones, which reduces the occurrence and/or severity of substrate defects by at least 50% as compared to conventional operations. Additionally, the increased hole density towards the outside of the faceplate reduces buildup and resultant defects from buildup detachment.

Subsequent to operation 506, one or more additional processes including film formation are executed on the first substrate at operation 508, or the first substrate is either removed from the process chamber at operation 510. In an example where a second process is executed at operation 508 while the first substrate is in the process chamber, the temperature of the gas distribution assembly is from about 270° C. to about 350° C. The temperature of the gas distribution assembly at operation 508 can be greater than, less than, or equal to the temperature of the gas distribution assembly at either or both of operations 504 or 506. In some examples, at operation 508, the temperature of the gas distribution assembly can be raised, lowered, or held from about 270° C. to about 350° C. In one example, operation 508 is optional in the method 500 and can be omitted.

In one example, there is no cleaning operation executed in between operation 504 and operation 506, and, in another example, one or more cleaning operations (not shown in FIG. 5) can be executed in between operations 504 and 506. In another example, the first substrate is removed from the process chamber at operation 510. At operation 512, subsequent to removal of the first substrate, the temperature of the gas distribution assembly is maintained from about 270° C. to about 350° C. In some embodiments, at operation 512, the substrate support can be maintained from about 250° C. to about 350° C. after the first substrate is removed at operation 510.

At operation 514, a second substrate is positioned on the substrate support in the process chamber. The second substrate can be bare, or the second substrate can include one or more previously formed and/or patterned films. At operation 516, one or more operations are executed on the second substrate while the gas distribution assembly temperature is maintained from about 270° C. to about 350° C. The temperature of the gas distribution assembly at operation 516 can be greater than or less than the temperature of the gas distribution assembly at some or all of operations 504, 506, 508, 512, or 514. In some examples, an average temperature of the gas distribution assembly is within ±20% of the temperature of the substrate support during some or all operations 506, 508, and 516. In other examples, the average temperature of the gas distribution assembly is within ±10% of the temperature of the substrate support during some or all operations 506, 508, and 516.

The semiconductor devices fabricated using the systems and methods discussed herein can include memory such as 3D NAND memory where memory cells are stacked vertically in multiple layers. The vertical stacking increases a thickness of films formed and/or patterned in the process chambers discussed herein. In one example, the process chambers discussed herein are configured to use tetraethyl orthosilicate (TEOS) oxides for applications including staircase fill applications. Staircase fill applications can be sensitive to substrate defects which can lead to low yield and high manufacturing costs. As vertical stacks used for 3D NAND memory increase in height, the process time and amount of gas(es) used for film formation increases, leading to increased buildup when conventional systems are employed.

In contrast, using the systems and methods discussed herein, operations including operations using TEOS can be executed while the resulting substrate defects can be reduced, increasing yield. In one example, the systems and methods discussed herein reduced substrate defects by more than 92% (from a first substrate fabricated using a conventional gas distribution assembly had 3000 adders/50 nm and a second substrate fabricated using the gas distribution assembly discussed herein that had about 30 adders/50 nm).

Using the systems and methods discussed herein, one or more operations can be executed in a process chamber without detrimental buildup of scale in dead zones. The gas distribution assembly can be held at temperature or adjusted within the range from about 270° C. to about 350° C. during and after a first operation is executed. Subsequently, a second operation on the same substrate or on a different substrate can be executed while the gas distribution assembly is at the elevated temperature. The gas distribution assemblies discussed herein include an inside edge that, when the gas distribution assembly is coupled to a process chamber, includes a radially-inward angled surface (relative to a chamber liner or sidewall) to promote a gas flow path away from the gas distribution assembly. This gas flow path is configured to reduce or eliminate dead zones and the resultant material buildup in dead zones that can lead to substrate defects. Additionally, one or more members of the gas distribution assembly are positioned within common dead zones within a process chamber, thereby occupying and eliminating the dead zones, thus also reducing material buildup.

Furthermore, using the heated gas distribution assemblies discussed herein, the frequency with which the gas distribution is cleaned is reduced, and the cleaning time is reduced at least in part because of the combination of the heating of the assembly and the reduced area of the faceplate that is available for buildup. Notably, increasing the temperature of the gas distribution assembly reduces buildup thickness, makes the buildup more compressive (e.g., the buildup has better adhesion to the areas where the material builds up) and improves density and quality of film deposited in the dead zones. This reduces the likelihood and frequency of the buildup on the gas distribution assembly loosening, and therefore reduces the occurrence and severity of substrate defects related to buildup in and flaking from dead zones.

To facilitate understanding, identical reference numerals have been used, where possible, to designate identical elements that are common to the figures. It is contemplated that elements and features of one embodiment may be beneficially incorporated in other embodiments without further recitation.

While the foregoing is directed to embodiments of the present disclosure, other and further embodiments of the disclosure may be devised without departing from the basic scope thereof, and the scope thereof is determined by the claims that follow.

What is claimed is:

1. A process chamber, comprising:
a gas distribution assembly disposed in the process chamber, the gas distribution assembly comprising:
a faceplate comprising a first portion including a plurality of apertures formed therethrough and a second portion disposed radially outward of the first portion, the second portion including a planar surface;
at least one heating element embedded in the faceplate; and
a member coupled to the second portion of the faceplate, the second member located on a process-region side of the faceplate and surrounding the plurality of apertures.

2. The process chamber of claim 1, wherein the member is a ring, and wherein an internal diameter of the member is greater at an upper end thereof relative to a lower end thereof.

3. The process chamber of claim 1, further comprising a liner disposed adjacent to the second portion of the faceplate and the member, wherein a first outer surface of the member is in contact with the liner, wherein a second outer surface of the member is in contact with the second portion of the faceplate, and wherein an inner surface of the member connects the first outer surface to the second outer surface.

4. The process chamber of claim 3, wherein the first outer surface of the member is disposed at a first angle of about 1 degrees to about 89 degrees to the inner surface of the member, and wherein the second outer surface of the member is disposed at a second angle of about 90 degrees minus the first angle to the inner surface of the member.

5. The process chamber of claim 4, wherein the first angle is smaller than the second angle.

6. The process chamber of claim 4, wherein the first angle and the second angle are substantially equal.

7. The process chamber of claim 3, wherein the inner surface is concave.

8. The process chamber of claim 1, wherein the first portion has a diameter less than a diameter of the faceplate.

9. A method of using a process chamber, comprising:
heating a faceplate of a gas distribution assembly disposed in a process chamber opposite a substrate support to a first temperature, the faceplate comprising a plurality of apertures formed therethrough, wherein a member is coupled to the faceplate, the member being located on a process-region side of the faceplate and surrounding the plurality of apertures;
heating the substrate support disposed in the process chamber to a second temperature;
providing, via the plurality of apertures of the faceplate, a first gas to the process chamber while the member coupled to the faceplate directs the first gas away from a perimeter of the faceplate; and
in response to providing the first gas to the process chamber, at least one of:
forming a first film on the substrate; or
removing at least a portion of a previously-formed film on the substrate.

10. The method of claim 9, wherein the faceplate comprises a first portion having the plurality of apertures formed therethrough and a second portion disposed radially outward of the first portion, the second portion including a planar surface.

11. The method of claim 10, further comprising a liner disposed adjacent to the second portion of the faceplate and the member, wherein a first outer surface of the member is in contact with the liner, wherein a second outer surface of the member is in contact with the second portion of the faceplate, and wherein an inner surface of the member connects the first outer surface to the second outer surface.

12. The method of claim 11, the first outer surface of the member is disposed at a first angle of about 1 degrees to about 89 degrees to the inner surface of the member, and wherein the second outer surface of the member is disposed at a second angle of about 90 degrees minus the first angle to the inner surface of the member.

13. The method of claim 12, wherein the first angle is smaller than the second angle.

14. The method of claim 12, wherein the first angle and the second angle are substantially equal.

15. The method of claim 11, wherein the inner surface is concave.

16. The method of claim 9, wherein the first temperature is from about 270° C. to about 350° C., and wherein the second temperature is from about 250° C. to about 350° C.

17. A process chamber, comprising:
a liner disposed along a wall of the process chamber;
a gas distribution assembly, the gas distribution assembly comprising:
a faceplate comprising a first portion including a plurality of apertures formed therethrough and a second portion disposed radially outward of the first portion, the second portion including a planar surface;
at least one heating element embedded in the faceplate; and
a member coupled to the second portion of the faceplate, the member located on a process-region side of the faceplate, wherein a first outer surface of the member is in contact with the liner, a second outer surface of the member is in contact with the second portion of the faceplate, and an inner surface of the member connects the first outer surface to the second outer surface; and a substrate support disposed opposite the gas distribution assembly; and
a power supply coupled to the at least one heating element in the gas distribution assembly and to the substrate support.

18. The process chamber of claim 17, wherein the first outer surface of the member is disposed at a first angle of about 1 degrees to about 89 degrees to the inner surface of the member, and wherein the second outer surface of the member is disposed at a second angle of about 90 degrees minus the first angle to the inner surface of the member.

19. The process chamber of claim 18, wherein the first angle is smaller than the second angle.

20. The process chamber of claim 18, wherein the inner surface is concave.
